(19) United States
(12) Patent Application Publication
(10) Pub. No.: US 2005/0205961 A1
(43) Pub. Date: Sep. 22, 2005

(54) Model-based insertion of irregular dummy features

(75) Inventor: Yih Yuh Doong, Shin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/875,428

(22) Filed: Jun. 24, 2004

Related U.S. Application Data
(60) Provisional application No. 60/555,174, filed on Mar. 22, 2004.

(51) Int. Cl. H01L 29/00; H01L 21/8238

(52) U.S. Cl. 257/499; 438/218; 438/294

(57) ABSTRACT

A semiconductor device includes an electric circuit, a first conductive feature coupled to the electric circuit, a dielectric material isolating the first conductive feature, and at least two second conductive features having irregular shapes, proximate to the first conductive feature and not electrically coupled to the electric circuit.

### CROSS REFERENCE

This application is related to, and claims priority of, U.S. Provisional Patent Application Ser. No. 60/555,174 filed on Mar. 22, 2004.

### BACKGROUND

The dual damascene process is generally adopted in semiconductor fabrication when feature size is scaled down and technology node moves to submicron. In the dual damascene process, copper is generally used as conductive material for interconnection. Other conductive materials include tungsten, titanium, titanium nitride. Accordingly, silicon oxide, fluorinated silica glass, or low dielectric constant (k) materials are used for inter-level dielectric (ILD). Chemical mechanical polishing (CMP) processing is implemented to etch back and globally planarize wafer surface. CMP involves both mechanical grinding and chemical etching in the material removal process. However, because the removal rate of metal and dielectric materials are usually different, polishing selectivity leads to undesirable dishing and erosion effects. Dishing occurs when the copper recedes below or protrudes above the level of the adjacent dielectric. Erosion is a localized thinning of the dielectric.

Dishing and erosion are sensitive to pattern structure and pattern density. Dummy metal features are designed and incorporated into damascene structure to make pattern density more uniform to improve the planarization process.

Other processes using CMP also suffer from similar problems. For example, shallow trench isolation (STI) uses CMP to etch back and form a global planarized profile. Over-etching is typically performed to ensure a complete etch of the silicon oxide on silicon nitride. Surface variations associated with local pattern and pattern density may be eliminated by the use of dummy features such as dummy active features in STI trench.

Dummy features formed by current methods may enhance pattern spatial signature but may not effectively compensate step height variation.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1A-1D are cross-sectional views of dishing and erosion in a semiconductor wafer, caused by chemical mechanical polishing processing.

FIG. 2 is a cross-sectional view of one example of dummy features fabricated in a semiconductor wafer.

FIG. 3 is a plan view of one embodiment of irregular dummy features in a semiconductor wafer constructed according to aspects of the present disclosure.

FIG. 4 is a schematic view of several embodiments of irregular dummy features used in semiconductor devices constructed according to aspects of the present disclosure.

FIG. 5 is a schematic view of one embodiment of density matrix constructed according to aspects of the present disclosure.

FIG. 6 is a flow chart of one embodiment of a method to develop dummy insertion infrastructure for new technology constructed according to aspects of the present disclosure.

FIG. 7 is a flow chart of one embodiment of a method to design dummy feature for a new product using a given technology constructed according to aspects of the present disclosure.

FIGS. 8A and 8B are graphs of one embodiment of mean pattern density shift and standard deviation shift, respectively, constructed according to aspects of the present disclosure.

FIG. 9 is a cross-sectional view of one embodiment of an integrated circuit in semiconductor substrate constructed according to aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

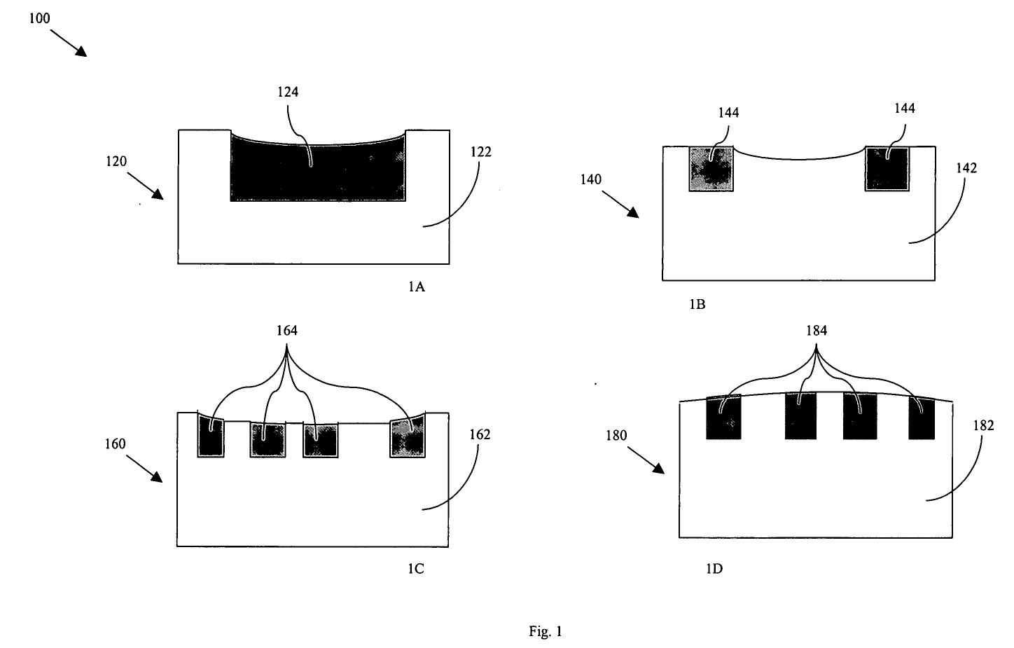

FIG. 1 is a cross-sectional view 100 of four examples of dishing and erosion effects in a semiconductor wafer caused by chemical mechanic polishing (CMP). In FIG. 1A, a semiconductor device 120 in the semiconductor wafer exhibits dishing when metal 124 has a higher polishing rate than that of dielectric material 122. The dielectric material 122 may include silicon oxide, fluorinated silica glass (FSG), low k materials, or combinations thereof. The metal 124 may include copper, tungsten, titanium, titanium nitride, tantalum, tantalum nitride, or combinations thereof. The dielectric 122 and the metal 124 may be part of interconnection structure in a integrated semiconductor circuit and may be fabricated by dual damascene processing including multiple processes such as deposition, etching, and CMP. When removal rate of the metal feature 124 is higher than that of the dielectric feature 122 in a polishing process such as CMP, a substantial deviation of surface profile from a flat one is referred to as dishing.

In FIG. 1B, a semiconductor device 140 exhibits dishing when dielectric material 142 has a higher polishing rate than that of metal 144. When the removal rate of the dielectric 142 is higher than that of the metal 144, a substantial deviation of surface profile from a flat one is referred to as dishing.

In FIG. 1C, a semiconductor device 160 exhibits erosion when a dielectric material 162 has a higher polishing rate than that of metal 164. When the removal rate of the dielectric 162 is higher than that of the metal 164, a substantial deviation of surface profile from a flat one is referred to as erosion.

In FIG. 1D, a semiconductor device 180 exhibits erosion when a dielectric material 182 has a higher polishing rate than that of metal 184. When the removal rate of the metal 184 is higher than that of the dielectric 182, a substantial deviation of surface profile from a flat one is also referred to as erosion.

The semiconductor devices 120, 140, 160, and 180 may further include electric circuits and semiconductor substrate. The electric circuits may include metal oxide semiconductor filed effect transistors (MOSFET), bipolar transistors, diodes, memory cells, resistors, capacitors, inductors, high voltage transistors, sensors, or combinations thereof. The semiconductor substrate may comprise an elementary semiconductor (such as crystal silicon, polycrystalline silicon, amorphous silicon and germanium), a compound semiconductor (such as silicon carbide and gallium arsenic), an alloy semiconductor (such as silicon germanium, gallium arsenide phosphide, aluminum indium arsenide, aluminum gallium arsenide and gallium indium phosphide) and/or combinations thereof. The semiconductor substrate may be a semiconductor on insulator, such as silicon on insulator (SOI), having a buried oxide (BOX) structure. In other examples, compound semiconductor substrate may include a multiple silicon structure, or the silicon substrate may include a multilayer compound semiconductor structure.

Dishing and erosion may also result from forming an isolation structure such as shallow trench isolation (STI) by CMP. Such STI, for example, may be formed by dry etching a trench in a substrate and filling the trench with insulator materials such as silicon oxide, low k materials, or combinations thereof. Silicon nitride may be used as an etch stop layer (ESL) to protect active areas between STI regions. The filled trench may have multi-layer structure such as a thermal oxide liner layer plus silicon oxide by chemical vapor deposition (CVD) or low k material. When CMP processing is used to etch back and planarize the semiconductor surface, polishing selectivity, between silicon oxide and silicon nitride, may cause dishing.

Both dishing and erosion effects are related to pattern density. To eliminate dishing and erosion in planarization processing including CMP processing in STI formation and CMP processing in interconnection formation, dummy feature may be used to improve pattern density and reduce deviations from a flat profile.

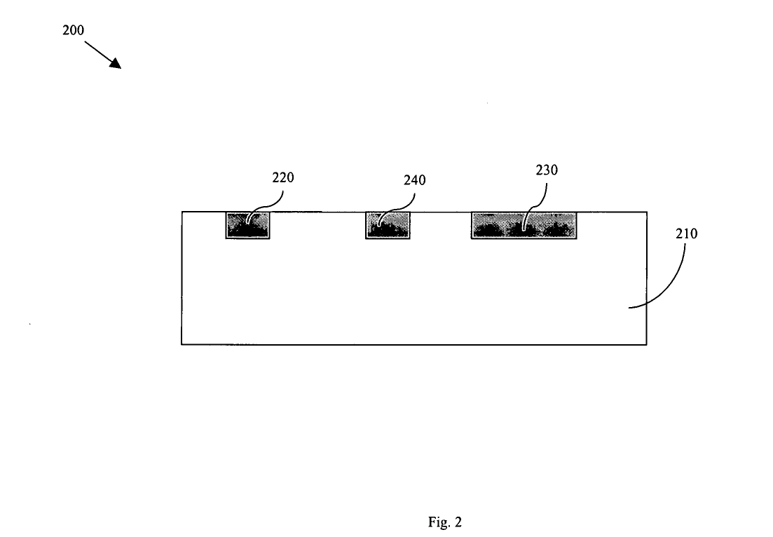

FIG. 2 is a cross-sectional view of one example of dummy features fabricated in a semiconductor device 200. Semiconductor device 200 includes a dielectric material 210 and metal features 220, 230, and 240. Dielectric 210 may include silicon oxide, FSG, low k materials, or combination thereof. Metal features 220, 230, and 240 may include copper, tungsten, titanium, titanium nitride, or combinations thereof. The metal features 220 and 240 may be electrically connected to underlying circuits and overlying bonding pads, while the metal feature 230 is not electrically connected to any functional circuits or bonding pads. Instead, the metal feature 230 is electrically isolated, and is referred to as a dummy feature. Such a dummy feature may be used to adjust local pattern density for better polishing effect.

Similarly, dummy features may also be used in forming STI isolation structures for better planarization effect. In one embodiment, dummy active regions may be formed in isolation or in a dummy-available region to improve uniformity of the pattern for better planarization in CMP process. In following description, focus will be on dummy structure and method to fabricate the same in multilayer interconnection. However, the spirit and the method of the present disclosure can be extended to dummy feature insertion in STI structure to enhance planarization.

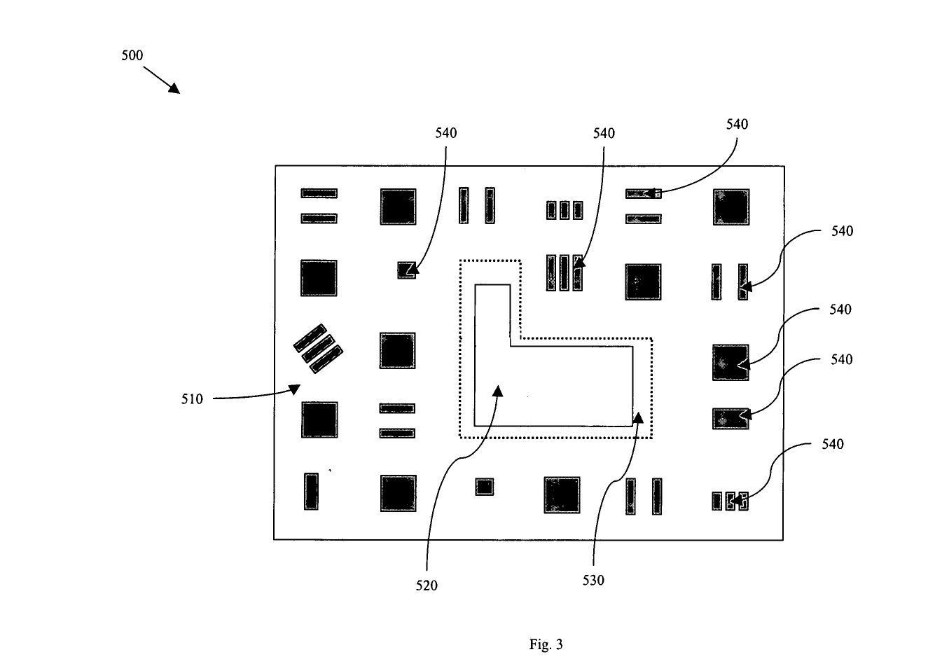

FIG. 3 is a schematic view of one embodiment of dummy feature insertion in a semiconductor device 500 constructed according to aspects of the present disclosure. The semiconductor device 500 may include a dielectric material 510 and a metal feature 520 as part of an integrated device. The dielectric 510 may include silicon oxide, FSG, low k materials, or combinations thereof. The metal feature 520 may include copper, tungsten, titanium, titanium nitride, tantalum, tantalum nitride, or combinations thereof. An area 530 is defined around the metal feature 520 as an exclusive zone prohibiting dummy feature insertion. Other than the exclusive zone 430, a group of irregular-shaped and sized dummy metal features 540 are formed in the dielectric material 510. The irregular dummy metal 540 generally comprises the same materials as those of metal feature 520.

In particular, dummy features 540 have irregular instead of predefined shape. The irregular dummy features 540 may have different shape, size, and thickness. The method of designing irregular dummy features can be referred to as model-based irregular dummy feature insertion. The model-based irregular dummy feature insertion uses irregular features and also allows local density and insertion location to vary for better uniformity, less parasitic resistance and capacitance, and less step height variation. Furthermore, the irregular dummy feature insertion method may generate irregular dummy features for insertion in a random manner. The irregular dummy feature insertion method may also use random placement including random location and random orientation of the dummy features. Such irregular dummy features with random generation and random placement is operable to reduce or eliminate pattern spatial signature and parasitic resistance/capacitance, reduce step height variation, and enhance planarization.

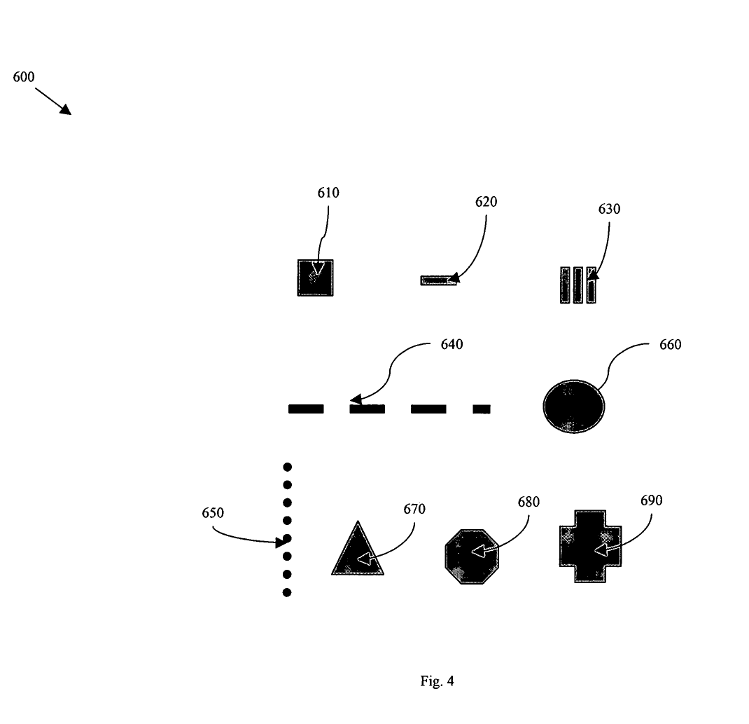

FIG. 4 is a schematic view of several embodiments of irregular dummy features 600. The irregular dummy features 600 may include, for example, a square 610, a rectangular 620, a rectangle array 630, a broken stripe 640, a dotted stripe 650, a circle 660, a triangle 670, polygon 680, and a cross 690. The above list only provides a few exemplary embodiments. Other suitable shapes based on the spirit of the present disclosure may also be considered as irregular dummy features for the same purpose. These irregular dummy features may have different sizes and thicknesses, and maybe placed randomly in location and orientation.

More generally, the irregular dummy feature may be constructed of metal or other conductive materials used in multilayer interconnection. The conductive material may include copper, tungsten, titanium, titanium nitride, or combinations thereof. The irregular dummy feature may also be a dummy active feature used in STI. The dummy active feature may comprise silicon, polysilicon, silicon oxide, and silicon nitride. The irregular dummy features may have a multiple layer structure for compatibility with functional features and better planarization effect.

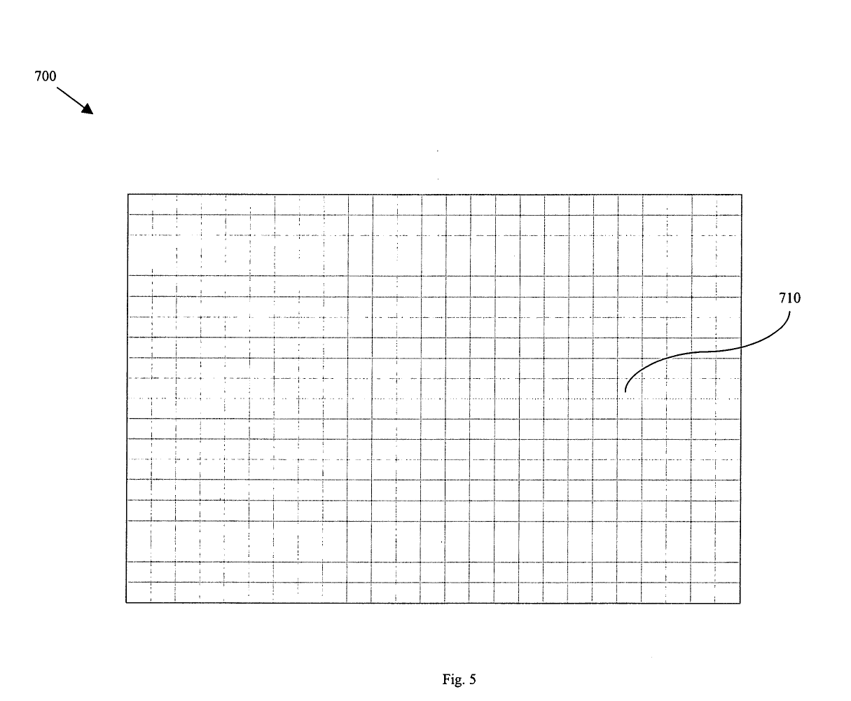

FIG. 5 is a schematic view of one embodiment of a density matrix 700 constructed according to aspects of the present disclosure. Prior to inserting dummy features, a targeted wafer area to be filled with dummy features is partitioned into an M×N grid. The partition size of the wafer area may depend on technology and process specification. For example, if technology node scaled down to small feature size, the partition may be down-scaled as well. In another example, if the polishing pad used in CMP processing is sufficiently hard so that polishing is not sensitive to local structures, the partition size may be scaled larger. Numeral 710 references an arbitrary partition which is in the i^{th} row and j^{th} column. The density of the partition in the i^{th} row and j^{th} column is presented by Sᵢⱼ and can be randomly generated according to model described below. Parameters related to irregular dummy feature insertion are defined as:
Dᵢⱼ is the density of as-designed pattern in i^{th} row and jth column;
Sᵢⱼ is the dummy feature pattern density in i^{th} row and jth column;
Fᵢⱼ is the total (or final) pattern density in i^{th} row and jth column where
   Fᵢⱼ=Dᵢⱼ+Sᵢⱼ; (1)
Uᵢⱼ is the upper limit of final pattern density in i^{th} row and j^{th} column;
k is the window size of averaging in calculation of an objective function defined below;
μᵢⱼ is the average of total pattern density Fᵢⱼ over an area with i^{th} row and j^{th} column as a center and with a radius of k partitions where

$${µ}_{ij} = \sqrt{\frac{{\sum }_{m = i - k}^{i + k} {\sum }_{n = j - k}^{j + k} {F}_{mn}}{{( 2 k + 1 )}^{2} - 1}} ; and \qquad ( 2 )$$
σᵢⱼ is the standard deviation of the total pattern density Fᵢⱼ over a range having a radius of k partitions where

$${σ}_{ij} = \sqrt{\frac{{\sum }_{m = i - k}^{i + k} {\sum }_{n = j - k}^{j + k} {( {F}_{mn} - {µ}_{ij} )}^{2}}{{( 2 k + 1 )}^{2} - 1}} \qquad ( 3 )$$

An expression

$${\sum }_{i} {\sum }_{j} \frac{{σ}_{ij}}{{µ}_{ij}}$$

is defined as an objective function. Minimizing the objective function under a certain condition may be used to determine dummy feature density:

$$Min ( {\sum }_{i} {\sum }_{j} \frac{{σ}_{ij}}{{µ}_{ij}} ) , such that {F}_{ij} \leq {U}_{ij} \qquad ( 4 )$$

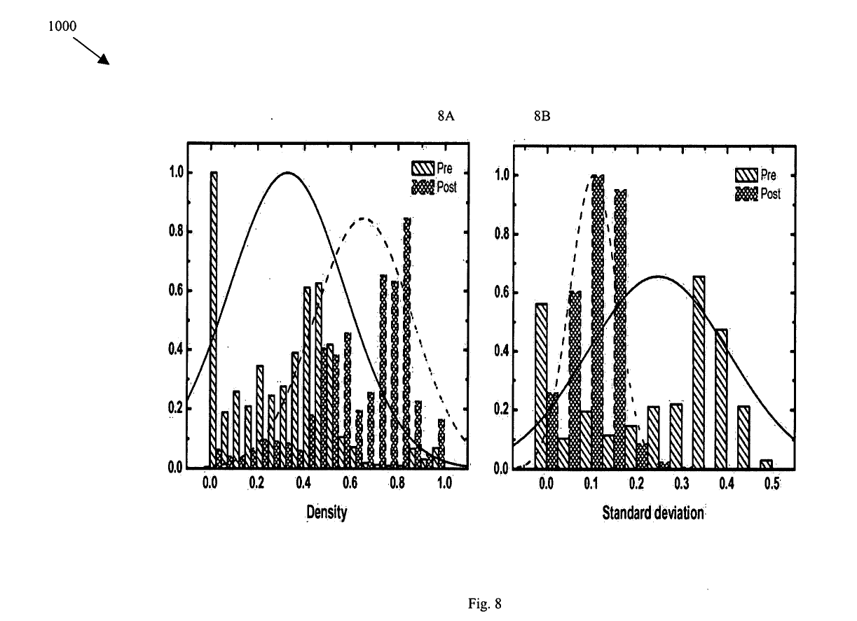

The minimization condition in Equation (4) states that the total pattern density of each partition, Fᵢⱼ, cannot be greater than the pattern density upper limit, Uᵢⱼ. The pattern density upper limit may be determined in a method shown in FIG. 8. According to an embodiment of the model-based irregular dummy feature insertion process, the average window size, k, is a measurement of pattern density interaction distance in CMP processing. The polishing result at one location is related to the pattern density in the partition that k or less partition away from the location. Generally, the window size, k, can be determined based on polishing processing parameters including metal materials, dielectric materials, CMP slurry, polishing pad, polishing pressure, and other parameters. The pattern density upper limit, Uᵢⱼ, can be determined by local as-designed metal structure and may be a function of location. After the window size, k, is determined by polishing processing, and the pattern density upper limit, Uᵢⱼ, is determined by as-designed metal structure, the average density of the final pattern, σᵢⱼ, and the standard deviation of the final pattern density, μᵢⱼ, can be determined by using above-described Equations (2) and (3), respectively. Then Equation (4) may be used to determine the final pattern density. Accordingly, the dummy feature density may be obtained with the total pattern density in Equation (1).

Based on thus determined dummy feature pattern density, an irregular dummy feature may be adopted. A candidate dummy feature may include all dummy features illustrated in FIG. 4 but is not so limited. In addition, the size and thickness of a chosen dummy feature may be randomly generated to fit in the above-calculated dummy pattern density. Furthermore, the dummy feature may be inserted in a location and orientation which can also be randomly determined, or randomly determined under certain conditions. Irregular dummy features and random insertion can eliminate pattern spatial signature and reduce step height variation.

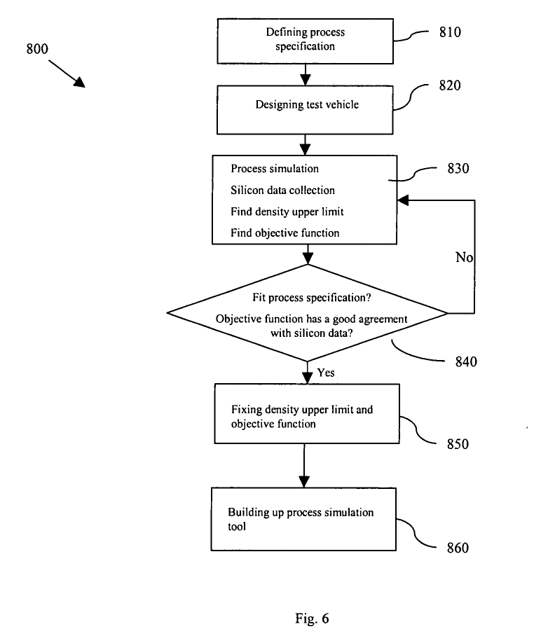

FIG. 6 is a flowchart of an embodiment of a method 800 to determine dummy insertion. Process 800 may be particular suited for newly developed semiconductor processes and techniques, such as when technology node moves from 0.13 micron to 0.09 micron, for example. New technology may include may include new or different semiconductor materials, semiconductor processing tools, semiconductor circuit design, fabrication conditions and parameters. For example, the use of ILD dielectric materials ranging from silicon oxide, fluorinated silica glass (FSG), and low k materials such as Black Diamond® (Applied Materials of Santa Clara, Calif.), Xerogel, Aerogel, amorphous fluorinated carbon, Parylene, BCB (bis-benzocyclobutenes), and SiLK (Dow Chemical, Midland, Mich.), may require that the CMP parameters to be modified accordingly.

The method 800 begins at step 810 by defining process specification. In one embodiment for interconnection planarization, processing specification may include the specification of metal material, metal line dimension, ILD dielectric materials, flatness variation tolerance, CMP processing parameters such as polishing pad hardness, pad type, polishing slurry formula, polishing pressure, rotation speed, polishing rate, and polishing selectivity.

The method 800 proceeds to step 820 in which a characterization test vehicle (“test vehicle”) is designed to collect dummy insertion data and calibrate the effect of irregular dummy feature insertion. A test vehicle is a semiconductor pattern specifically designed for certain tests and experiments. A test vehicle may consist a set of electrical reference test structures which are next to metal structures including as-designed metal lines compatible with the new technology and dummy features of different combinations of shapes, size, thickness, location, and orientation. In one embodiment, a Kelvin resistor is adopted as an electrical reference test structure because Kelvin resistors may provide higher electrical measurement accuracy. In designing a test vehicle, metal lines of various dimensions and densities may be included in the pattern structure in the test vehicle. The test vehicle may include various predefined features and patterns such as those described in FIG. 3 so that all these features may be evaluated to determine the pattern density upper limit and the objective function. In one application, a test vehicle may be a semiconductor area or a semiconductor die, or a semiconductor wafer with specifically designed pattern. In one embodiment, the targeted area or whole wafer area is partitioned into an M×N grid as shown in FIG. 5.

In step 830, the test vehicle designed in step 820 is used to simulate the polishing process. Test data is collected, which includes polishing rate, polishing selectivity, surface level variation, and relationship between polishing results (including polishing rate and surface level variation) and pattern structures including pattern density. In one embodiment, the collected data may be used to determine the average window size, k, or/and pattern density upper limit, Uᵢⱼ. Pattern density has a universal maximum limit for a given technology. For example, metal density may not be more than 75%. However, for a given as-designed metal pattern, available space for dummy metal insertion may be much less. So each tile may have a local pattern density upper limit associated with local as-designed pattern structure and pattern density. Step 830 may determine the pattern density upper limit through simulation and calculation. Such pattern density upper limit may be used in dummy feature tiling. In step 830, the objective function defined in Equation (4) may be calculated using different average window size and extracted pattern density upper limit. Collected data in step 830 may also include resistance and capacitance data of the test vehicle that reveal the parasitic resistance and capacitance added to the as-designed structure. The evaluation of polishing result and parasitic resistance/capacitance from the test vehicle may be compared with the calculated objective function to verify if they are in agreement and if the objective function is well constructed and effective.

In step 840, some criteria are used to evaluate above the test, simulation, and calculation to determine whether the average window size is in agreement with the process specification defined in step 810. Furthermore, if the calculated objective function is in agreement with data collected from CMP processing and the test structure of the test vehicle. If either one or both of the questions have a negative answer, execution returns to the step 830. Otherwise, the method proceeds to step 850.

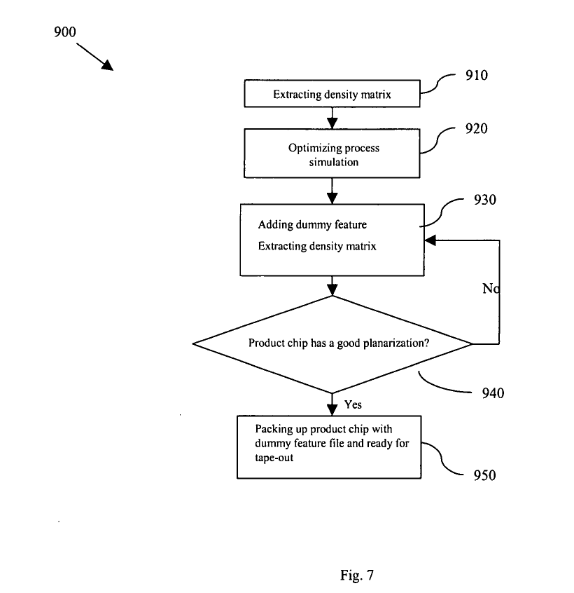

In step 850, pattern density upper limit and objective function determined in step 840 are recorded for each given pattern structure. These recorded data may be used for dummy feature insertion for a new product, which will be described in method 900 provided in FIG. 7.

The method 800 proceeds to step 860 in which a process simulation tool is built according to the recorded data including the average window size, k, pattern density upper limit, Uᵢⱼ, and parasitic resistance/capacitance. The process simulation tool may include process specification, constructed objective function, irregular dummy feature database, and an irregular dummy feature generator. The process simulation tool may be used for irregular dummy feature tiling, polishing processing design, and polishing control.

FIG. 7 is a flowchart of an embodiment of a method 900 to design dummy features for a new product using a given technology. The given technology was defined in the process specification in step 810 of the method 800 in FIG. 6. When developing a new product using the given technology, dummy features may be designed and incorporated into integrated devices according to as-designed pattern structure.

The method 900 begins at step 910 by extracting a density matrix. The semiconductor wafer surface area is partitioned into M×N partitions. The partition is based on simulation and collected data in the method 800. As-designed pattern density, Dᵢⱼ, can be extracted from the as-designed pattern structure for the new product. The extraction may be implemented by process simulation tool.

The method 900 proceeds step 920, in which process simulation is optimized. The process simulation needs input of simulation parameters including average window size, k, pattern density upper limit, and generator to produce an irregular dummy feature. The input information may be available from implementation of the method 800 for the given technology associated with the new product. Some parameters may need to be modified and optimized according to the information of the density matrix and/or other information of the new product.

In step 930, dummy features are generated through simulation and added to the as-designed pattern according to process simulation and a certain algorithm defined through equation (1) to (4). Dummy features may be optimized through minimization of the objective function under the condition that total final density, Fᵢⱼ, of each partition may not be larger than the pattern density upper limit of the partition. The pool of dummy features are irregular dummy features of different shape, size, thickness, location, and orientation illustrated in FIG. 3. In one embodiment, for each partition, a dummy feature is randomly selected and evaluated by the pattern density upper limit of the partition. If it is out of range, then the dummy feature is discarded and a new dummy feature is randomly generated for evaluation until the total pattern density meets the pattern density upper limit in that partition. To select an irregular dummy feature for the partition, other filters may be used, including parasitic resistance/capacitance, and polishing results based on the collected data from the test vehicle. This process is reaped for each partition until all partitions have been evaluated. The objective function can be calculated for further evaluation.

In step 940, in one embodiment, the objective function is evaluated to determine if minimization is achieved. If the objective function is not minimized and the planarization may not meet specification, then the method 900 returns to step 930 and repeats the same process until the objective function is well below the values of the objective function with other irregular dummy features and the objective function is minimized. Alternatively, a numerical value may be used as a criteria to evaluate if an objective function is minimized.

In step 950, the designed dummy feature is incorporated into the final product and recorded into design file and photomask tapeout file for photomask implementation and production fabrication.

FIG. 8 is an exemplary graph 1000 of one embodiment of mean metal density shift and standard deviation shift after irregular dummy feature insertion. The graph 1000 is a characterization of one embodiment of the irregular dummy feature insertion. Graph (a) shows the total pattern density distribution before and after dummy feature insertion. It may be seen that the pattern density distribution shifts to higher values after dummy feature insertion. Graph (b) is about standard deviation of the total pattern density distribution. The chart (b) shows that the standard deviation is substantially reduced and so the total pattern density uniformity is improved. Therefore, planarization by CMP processing may be improved because of uniform pattern density.

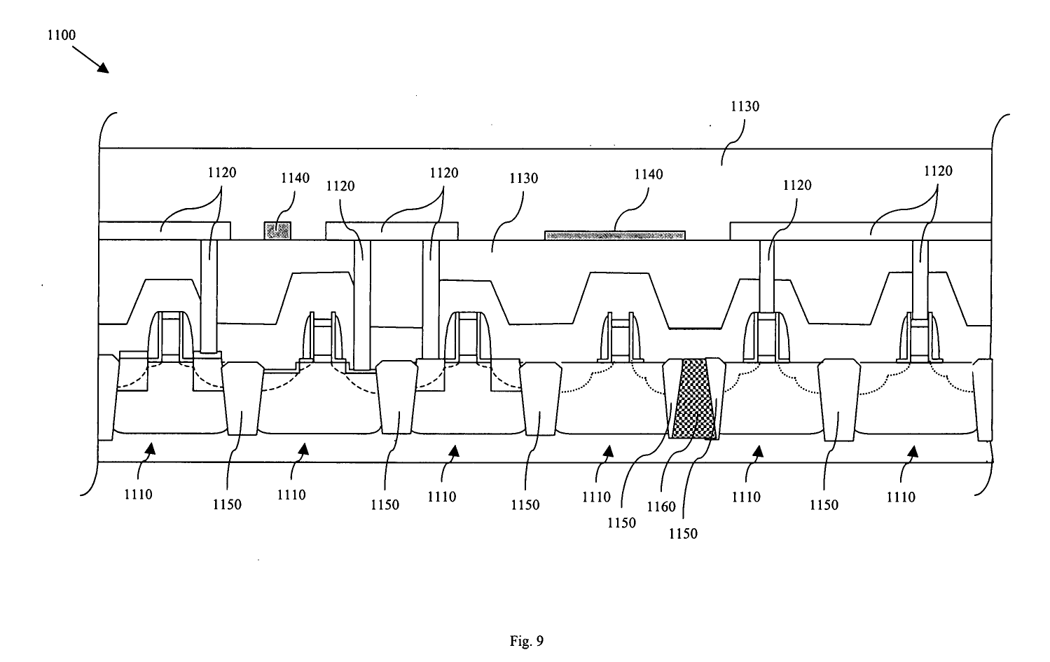

Referring to FIG. 9, one embodiment of an integrated circuit device 1100 is provided. The integrated circuit device 1100 is one environment in which embodiments of the semiconductor device 500 having irregular dummy features shown in FIG. 5 may be implemented. For example, the integrated circuit device 1100 includes a plurality of semiconductor devices 1110. The semiconductor devices 1110 may form a logic circuit, memory cells, or other transistor array, including a one-, two- or three-dimensional array, and may be oriented in one or more rows and/or one or more columns.

The integrated circuit device 1100 also includes interconnects 1120 extending along and/or through one or more dielectric layers 1130. The dielectric layer 1130 may comprise silicon dioxide, FSG, Black Diamond® (a product of Applied Materials of Santa Clara, Calif.), Xerogel, Aerogel, amorphous fluorinated carbon, Parylene, BCB, Flare, and SiLK, and/or other materials, and may be formed by CVD, ALD, PVD, spin-on coating and/or other processes. The interconnects 1120 may comprise copper, tungsten, titanium, titanium nitride, gold, aluminum, carbon nano-tubes, carbon fullerenes, refractory metals, alloys of these materials and/or other materials, and may be formed by CVD, PVD, plating and/or other processes. The interconnects 1120 may also include more than one layer. For example, each interconnect 1120 may comprise an adhesion layer possibly comprising titanium, titanium nitride, tantalum or tantalum nitride, a barrier layer possibly comprising titanium nitride or tantalum nitride, and a bulk conductive layer comprising copper, tungsten, aluminum, or aluminum alloy. The interconnect 1120 may further include at least one irregular dummy feature 1140, wherein the irregular dummy feature 1140 is inserted into inter-level dielectric 1130 according to disclosed method and is not electrically connected to underlying functional circuit. The irregular dummy feature may use the same materials and processing as these of the interconnect 1120.

The semiconductor substrate 1110 may be a semiconductor on insulator, such as SOI, having a BOX structure. In other examples, compound semiconductor substrate may include a multiple silicon structure, or the silicon substrate may include a multilayer compound semiconductor structure. The semiconductor substrate 1110 may include a plurality of isolation trench structures 1150 between active region for isolation. Furthermore, a dummy active feature 1160 may be formed in isolation region to improve pattern uniformity for better polishing processing. The dummy active feature may have irregular shape. The dummy active feature 1160 may include silicon or polysilicon. The dummy active feature 1160 may further include a pad oxide layer and silicon nitride layer which are substantially removed after polishing processing. Alternatives to silicon nitride may include silicon oxynitride and silicon carbide. The irregular dummy features 1140 and 1160 may have random shape, random size, random thickness, random location, and random orientation. The random shape may include a square, a rectangle, a rectangular array, a broken stripe, a dotted stripe, a circle, a triangle, polygon, and a cross.

Thus, the present disclosure introduces a semiconductor device including, in one embodiment, an irregular dummy feature located in inter-level dielectric. The irregular dummy feature may have random shape, size, thickness, location, orientation, or combination thereof. In another embodiment, semiconductor device constructed may comprise an dummy active feature located in isolation region.

The present disclosure also introduces a method of designing irregular dummy feature. In one embodiment, the method includes optimization flow for dummy insertion infrastructure. In another embodiment, the method includes dummy insertion optimization flow for a new product chip using existing fabrication technology.

An integrated circuit device is also provided in the present disclosure. In one embodiment, the integrated circuit device includes a plurality of semiconductor devices including at least one irregular dummy feature located in an inter-level dielectric. In another embodiment, the integrated circuit device includes at least one irregular dummy active feature located in isolation region in substrate.

Irregular dummy feature may have multi-level structure compatible with multilevel interconnection structure to enhance metal pattern density uniformity.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A semiconductor device, comprising:
an electrical circuit;
a first conductive feature coupled to the electrical circuit;
a dielectric material electrically isolating the first conductive feature; and
at least two second conductive features having irregular shapes, proximate to the first conductive feature and electrically isolated from the electrical circuit.

2. The semiconductor device of claim 1 wherein the at least two second conductive features have irregular shapes selected from the group consisting of a square, a rectangle, a rectangular array, a broken stripe, a dotted stripe, a circle, a triangle, polygon, and a cross.

3. The semiconductor device of claim 1 wherein the at least two second conductive features have random sizes.

4. The semiconductor device of claim 1 wherein the at least two second conductive features have random thicknesses.

5. The semiconductor device of claim 1 wherein the at least two second conductive features have random locations.

6. The semiconductor device of claim 1 wherein the at least two second conductive features have random orientations.

7. The semiconductor device of claim 1 wherein the at least two second conductive features comprise copper.

8. The semiconductor device of claim 1 wherein the at least two second conductive features are constructed of materials selected from the group consisting of copper, tungsten, titanium, titanium nitride, tantalum, and tantalum nitride.

9. The semiconductor device of claim 1 wherein the at least two second conductive features have multi-layer structure.

10. The semiconductor device of claim 1 wherein the first conductive feature is constructed of materials selected from the group consisting of copper, tungsten, titanium, titanium nitride, tantalum, and tantalum nitride.

11. The semiconductor device of claim 1 wherein the dielectric material comprises silicon oxide.

12. The semiconductor device of claim 1 wherein the dielectric material comprises fluorinated silica glass.

13. The semiconductor device of claim 1 wherein the dielectric material comprises low k material.

14. The semiconductor device of claim 13 wherein the low k material is selected from the group consisting of Black Diamond, Xerogel, Aerogel, amorphous fluorinated carbon, Parylene, BCB (bis-benzocyclobutenes), and SiLK.

15. The semiconductor device of claim 1 wherein the at least two second conductive features have multilevel structure.

16. A semiconductor device, comprising:
an active region disposed in a substrate and comprising an electrical circuit;
an isolation region disposed in the substrate and proximate the active region; and
a dummy active feature having an irregular shape disposed in the isolation region.

17. The semiconductor device of claim 16 wherein the irregular shape is selected from the group consisting of a square, a rectangle, a rectangular array, a broken stripe, a dotted stripe, a circle, a triangle, polygon, and a cross.

18. The semiconductor device of claim 16 wherein the dummy active feature has a random size, thickness, location, and orientation.

19. The semiconductor device of claim 16 wherein the dummy active feature comprises substantially silicon and polysilicon.

20. The semiconductor device of claim 16 wherein the dummy active feature further comprises sacrificial layers of materials selected from the group consisting of silicon oxide, silicon nitride, silicon oxynitride, silicon carbide, or combination thereof, and the sacrificial layers are substantially removed after trench isolation polishing processing.

21. The semiconductor device of claim 16 wherein the substrate is a silicon-on-insulator (SOI) substrate.

22. A method to develop a dummy feature infrastructure for a semiconductor device, comprising:
defining a process specification for the semiconductor device;
designing a test vehicle wherein the test vehicle comprises:
a test structure designed to measure resistance and capacitance; and
at least two metal features having irregular shapes;
collecting data from the test vehicle, wherein the collecting data comprises:
polishing the test vehicle;
measuring surface profile of the polished test vehicle to collect polishing rate, polishing selectivity, and surface level variation; and
measuring resistance and capacitance in the test structure of the test vehicle;
determining a pattern density upper limit; and
determining an objective function.

23. The method of claim 22 further comprising building a process simulation tool.

24. The method of claim 22 further comprising determining an average window size of for calculation of the objective function.

25. The method of claim 24 wherein determining an objective function comprises:
averaging metal pattern density over an range defined by the average window size to obtain an average pattern density;
determining a standard deviation of the metal pattern density; and
summarizing the standard deviation over the average pattern density.

26. The method of claim 22 wherein the process specification comprises a specification of metal material, inter-level dielectric (ILD) materials, polishing processing tool, and polishing processing parameters.

27. The method of claim 26 wherein the process specification for the polishing processing tool comprises polishing pad hardness and polishing slurry formula.

28. The method of claim 26 wherein the process specification for the polishing processing parameters comprises polishing pressure and polishing selectivity.

29. The method of claim 22 wherein the test structure comprises a Kelvin resistor.

30. The method of claim 22 wherein the metal feature irregular shape is selected from the group consisting of a square, a rectangle, a rectangular array, a broken stripe, a dotted stripe, a circle, a triangle, polygon, and a cross.

31. A method comprising:
partitioning a surface of a semiconductor product into an M×N grid;
extracting a density matrix of the grid;
adding an irregular dummy feature to each partition of the density matrix; and
calculating an objective function and evaluating if the objective function is minimized.

32. The method of claim 31 further comprising packing up technical files for dummy feature design and tapeout files for photomask manufacturing.

33. The method of claim 31 wherein calculating the objective function comprises making the calculation under a condition that a total pattern density for each partition is less than a pattern density upper limit.

34. The method of claim 31 wherein adding an irregular dummy feature comprises generating an irregular dummy feature randomly.

35. The method of claim 34 wherein generating an irregular dummy feature randomly further comprises generating an irregular dummy feature with random shape, random size, random thickness, random location, and/or random orientation.

36. The method of claim 31 wherein the irregular dummy feature is selected from the group consisting of a square, a rectangle, a rectangular array, a broken stripe, a dotted stripe, a circle, a triangle, polygon, and a cross.

37. The method of claim 31 wherein the irregular dummy feature is selected from the group consisting of copper, tungsten, titanium, titanium nitride, tantalum, and tantalum nitride.

38. The method of claim 31 wherein the irregular dummy feature is selected from the group consisting of silicon, polysilicon, silicon oxide, silicon nitride, silicon oxynitride, and silicon carbide.
